(19) United States
(12) Patent Application Publication
(10) Pub. No.: US 2018/0252483 A1
(43) Pub. Date: Sep. 6, 2018

(54) HEATSINK STIFFENER METHOD AND APPARATUS

(71) Applicant: Intel Corporation, Santa Clara, CA (US)

(72) Inventors: Phil Geng, Portland, OR (US); Tejinder Pal S. Aulakh, Auburn, WA (US); Sandeep Ahuja, Portland, OR (US)

(21) Appl. No.: 15/446,791

(22) Filed: Mar. 1, 2017

(51) Int. Cl. F28F 19/00; F28F 3/12; F28F 3/06; G06F 1/20; H05K 7/20

(52) U.S. Cl. CPC F28F 19/002; F28F 3/12; F28F 3/06; H05K 7/20218; H05K 7/2039; F28F 2225/02; H05K 7/2029; G06F 1/20

(57) ABSTRACT

Apparatus and method to increase structural integrity of heatsinks are described herein. In embodiments, an apparatus may include a plurality of thermal dissipation fins; and a base disposed below the plurality of thermal dissipation fins, wherein the base is to include an evacuated space in which one or more thermal transport pipes and one or more stiffener structures are disposed, the evacuated space is to include a first side proximate to the plurality of thermal dissipation fins and a second side opposite the first side, and wherein a stiffener structure of the one or more stiffener structures attaches to the first or second side.

### FIELD OF THE INVENTION

The present disclosure relates generally to the technical fields of computing and thermal management, and more particularly, to improved thermal dissipation structures used in computing/electronic systems.

### BACKGROUND

The background description provided herein is for the purpose of generally presenting the context of the disclosure. Unless otherwise indicated herein, the materials described in this section are not prior art to the claims in this application and are not admitted to be prior art or suggestions of the prior art, by inclusion in this section.

With increasing computing requirements, and often, in limited or shrinking physical space in which to locate computing components, heat generation by the computing components may be considerable. Since thermal buildup may degrade computing performance and/or cause failures or permanent damage, mechanical thermal dissipation structures such as heat sinks may be implemented to dissipate the heat. In some embodiments, however, assembly requirements of the computing components to its associated heat sinks may also create undesirable effects. It may be advantageous to address such undesirable effects without the need to redesign entire assemblies or subassemblies of computing components, heat sinks, and/or other possible structures for the system at large.

### BRIEF DESCRIPTION OF THE DRAWINGS

Embodiments will be readily understood by the following detailed description in conjunction with the accompanying drawings. The concepts described herein are illustrated by way of example and not by way of limitation in the accompanying figures. For simplicity and clarity of illustration, elements illustrated in the figures are not necessarily drawn to scale. Where considered appropriate, like reference labels designate corresponding or analogous elements.

FIG. 1 depicts an exploded perspective view illustrating an example apparatus incorporating aspects of the present disclosure, according to some embodiments.

FIGS. 2A-2C depict example views of the heatsink, according to some embodiments.

FIG. 3 depicts an example cross sectional view of the heatsink, according to some embodiments.

FIG. 4 depicts locations which may comprise examples of possible stiffener structure locations, according to some embodiments.

FIGS. 5A-5B depict example views of the stiffener structures, according to some embodiments.

FIG. 6A depicts an illustration of simulated loads applicable to the heatsink in a finite element analysis (FEA) simulation, according to some embodiments.

FIG. 6B depicts an example graph illustrating FEA simulation results, according to some embodiments.

FIGS. 6C-6D depict examples of simulated deflection of the base with and without stiffener structures, according to some embodiments.

FIG. 7 depicts an example process for fabricating the base, according to some embodiments.

### DETAILED DESCRIPTION

Embodiments of apparatuses and methods related to improving structural integrity of heatsinks are described. In embodiments, an apparatus may include a plurality of thermal dissipation fins; and a base disposed below the plurality of thermal dissipation fins, wherein the base is to include an evacuated space in which one or more thermal transport pipes and one or more stiffener structures are disposed, the evacuated space is to include a first side proximate to the plurality of thermal dissipation fins and a second side opposite the first side, and wherein a stiffener structure of the one or more stiffener structures attaches to the first or second side. These and other aspects of the present disclosure will be more fully described below.

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. Additionally, it should be appreciated that items included in a list in the form of “at least one A, B, and C” can mean (A); (B); (C); (A and B); (B and C); (A and C); or (A, B, and C). Similarly, items listed in the form of “at least one of A, B, or C” can mean (A); (B); (C); (A and B); (B and C); (A and C); or (A, B, and C).

The disclosed embodiments may be implemented, in some cases, in hardware, firmware, software, or any combination thereof. The disclosed embodiments may also be implemented as instructions carried by or stored on one or more transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, it may not be included or may be combined with other features.

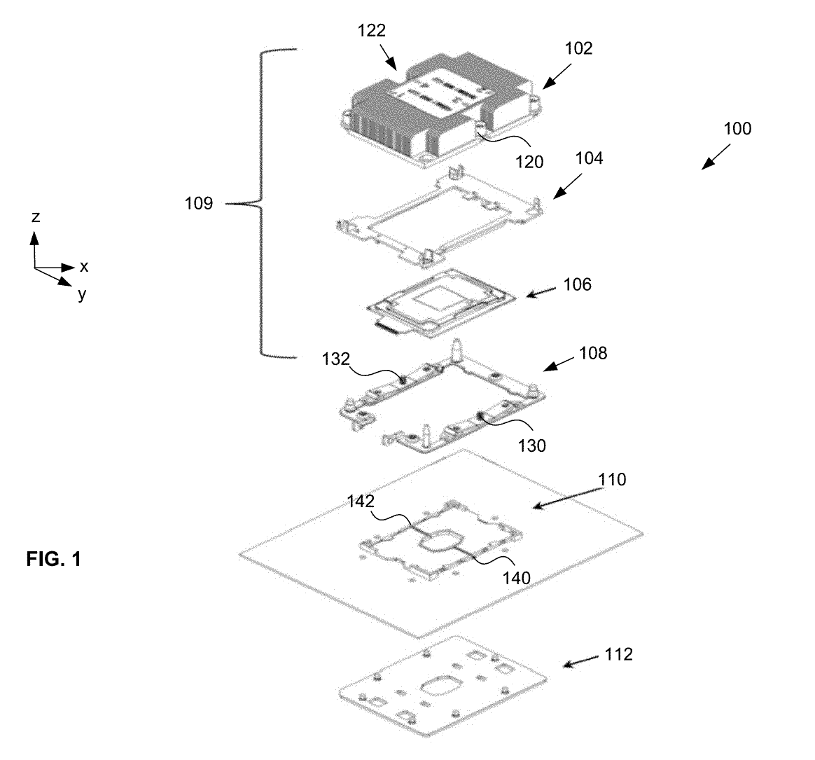

FIG. 1 depicts an exploded perspective view illustrating an example apparatus 100 incorporating aspects of the present disclosure, according to some embodiments. Apparatus 100 may also be referred to as a component stack, a stack, a component package, a component and heatsink stack, a component and heatsink assembly, a computing component and heatsink assembly, and the like. Apparatus 100 may include, without limitation, a heatsink 102, a component clip 104, a computing/electronic component 106, a top plate 108, a socket 110, and a back plate 112. Hereinafter, computing/electronic component 106 may simply be referred to as computing component 106.

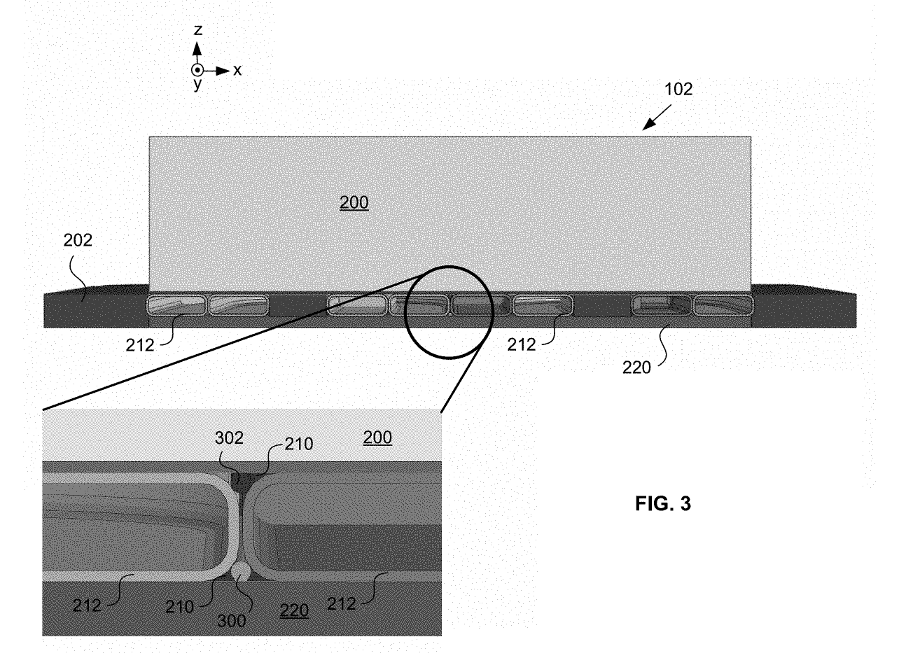

In some embodiments, the component clip 104 may be disposed between the heatsink 102 and the computing component 106 along a z-direction of a Cartesian coordinate system. Heatsink 102 may comprise a thermal dissipation structure for the apparatus 100, and in particular, configured to dissipate heat which may be generated by the computing component 106. Heatsink 102 may include a plurality of fins, one or more embedded heat pipes, and one or more stiffener structures, as described in detail below. The one or more stiffener structures, in some embodiments, may be configured to provide additional structural stiffness to at least a portion of the heatsink 102 (e.g., the base of the heatsink 102), thereby reducing deformation and/or maintaining electrical, thermal, reliability, and/or other requirements of the apparatus 100. FIG. 3 depicts the one or more stiffener structures included in the base 202, according to some embodiments (to be further described).

The component clip 104 may be configured to encircle or frame the computing component 106 and facilitate proper positioning of the computing component 106 relative to the heatsink 102 in the x-y plane. The computing component 106 may comprise one or more circuitry, chip, device, or the like such as, but not limited to, processors, central processing units (CPUs), graphic processing units (GPUs), controllers, interfaces, and the like. The component clip 104, heatsink 102, and computing component 106 may collectively be referred to as a component subassembly or module 109. When the computing component 106 comprises a processor, the component clip 104, heatsink 102, and computing component 106 may be referred to as a processor heatsink module (PHM) subassembly. The socket 110 may be disposed between the top plate 108 and the back plate 112 (also referred to as the bottom plate) along the z-direction, and the top plate 108 may also be disposed between the component subassembly/module 109 and the socket 110 along the z-direction.

In some embodiments, heatsink 102 may include mounting or attachment sockets 120, 122 located on or near edges of opposing sides of the heatsink 102 and at the midpoint (or near the midpoint) of the respective opposing sides of the heatsink 102. Each of the top plate 108 and socket 110 may include a corresponding pair of mounting/attachment structures 130, 132 and mounting/attachment structures 140, 142, respectively. Upon alignment and connection among the mounting/attachment socket 120, mounting/attachment structure 130, and mounting/attachment structure 140 and among mounting/attachment socket 122, mounting/attachment structure 132, and mounting/attachment structure 142, thermal and electrical coupling may be established among the various subcomponents within the apparatus 100.

In some embodiments, a load or compression force (substantially along the z-direction) in the range of approximately 130-300 pound force (lbf) may be present on the apparatus 100 upon use of the mounting/attachment sockets 120, 122 and mounting/attachment structures 130, 132, 140, 142 to form the stacked structure. Within such stacked structure (e.g., in between one or more of the heatsink 102, component clip 104, computing component 106, top plate 108, and socket 110) may also include one or more materials to facilitate thermal dissipation and/or thermal coupling to the heatsink 102. For example, a first level thermal interface material (TIM1), a second level thermal interface material (TIM2), and/or an integrated heat spreader (IHS) may be included.

Back plate 112 may be attached to the socket 110, such that the heatsink 102, component clip 104, computing component 106, top plate 108, socket 110, and back plate 112 may form a unitary structure (e.g., the apparatus 100). The unitary structure or at least selective portions of the unitary structure, in turn, may be attached and/or electrically coupled to a printed circuit board (PCB), a motherboard, a substrate, another computing component, electrical connectors, or the like.

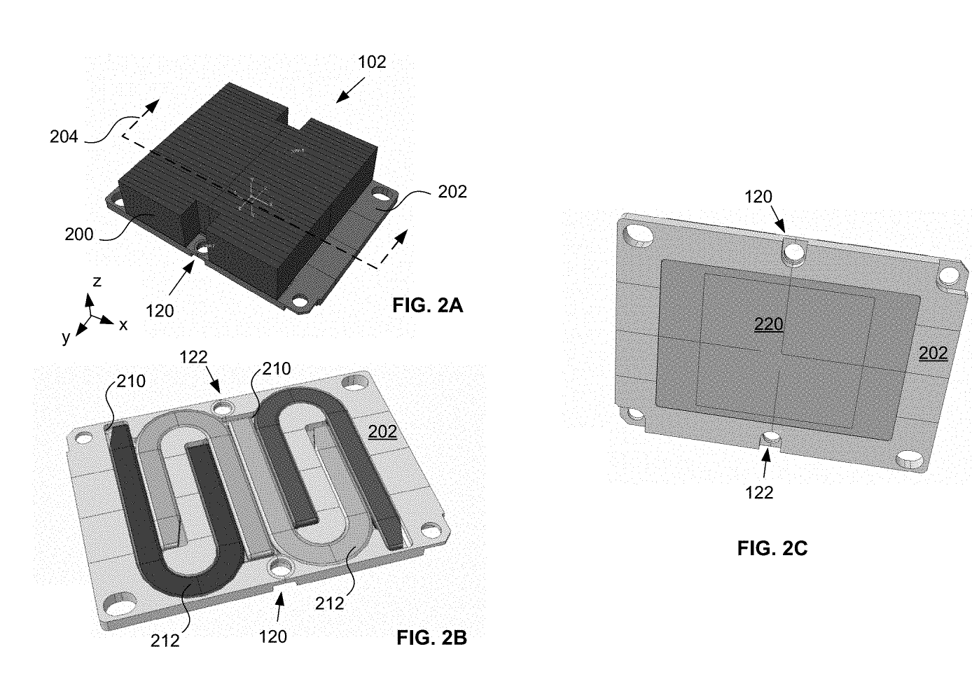

FIGS. 2A-2C depict example views of the heatsink 102, according to some embodiments. In FIG. 2A, the heatsink 102 may be depicted including a plurality of fins 200 attached or bonded to a base 202. The plurality of fins 200 may also be referred to as heatsink fins, heatsink projections, or the like; and the base 202 may also be referred to as a heatsink base. In some embodiments, each fin of the plurality of fins 200 may comprise a sheet of material that is substantially perpendicular to the base 202. Each fin may include major sides or surfaces in the x-z plane, and in which the fins of the plurality of fins 200 may be oriented parallel to each other along the y-direction. Alternatively, the major sides/surfaces of the fins may be provided in the y-z plane, some angle between the x-z and y-z planes, or the like. Fins 200 and base 202 may comprise metallic materials. Fins 200 and base 202 may comprise the same or different materials from each other. For example, base 202 may comprise aluminum material.

A side of the base 202 closest to the plurality of fins 200 (e.g., the top of the base 202) may be as depicted in FIG. 2B, according to some embodiments. Base 202 may include cutout or evacuated portions 210 into which one or more embedded heat pipes 212 may be located. The embedded heat pipes 212 (also referred to as thermal transport pipes or structures) may be configured to transport heat from originating sources (e.g., computing component 106) to the plurality of fins 200. In FIG. 2B, four embedded heat pipes 212 may be shown included in the base 202. Each of the embedded heat pipes 212 may be closed or sealed at both ends, and may be hollow, filled or partially filled with air, filled or partially filled with a gas mixture other than air, filled or partially filled with an aqueous or liquid solution, filled or partially filled with a solid or semi-solid solution, or the like. The material for the embedded heat pipes 212 and the internal contents of the embedded heat pipes 212 may be chosen in accordance with desired thermal dissipation properties, cost, manufacturing constraint, and the like. One or more of the embedded heat pipes 212 may the same or different from each other. The thickness of the embedded heat pipes 212 may be configured for the sides of the embedded heat pipes 212 closest to the fins 200 to be in contact with the fins 200.

Although four embedded heat pipes 212 may be shown in FIG. 2B, it is understood that fewer or more than four embedded heat pipes may be included in the base 202. For instance, rather than having four embedded heat pipes, a single continuous embedded heat pipe may be located in the same cutout/evacuated portions 210. The shape or contours of the cutout/evacuated portions 210 (also referred to as trenches or heat pipe trenches) and the embedded heat pipes 212 may also be of any shape or contour.

A side of the base 202 furthest from the plurality of fins 200, which may be the side opposing or opposite to the side shown in FIG. 2B, may be as depicted in FIG. 2C, according to some embodiments. The side shown in FIG. 2C may comprise the bottom of the base 202. The bottom side of the base 202 may include a central portion 220 which may be embedded into or planar with the bottom side/surface of the base 202. The central portion 220 may comprise a metallic material, such as copper. The central portion 220 may also be referred to a slug or embedded slug.

FIG. 3 depicts an example cross sectional view of the heatsink 102, according to some embodiments. A cross sectional view line 204 in FIG. 2A may be associated with the cross sectional view illustrated in FIG. 3. A major surface/side of a fin of the plurality of fins 200 may be seen in this view. The embedded heat pipes 212 may be disposed between the fin 200 and the central portion 220. The heatsink 102 may further include one or more stiffener structures, such as stiffener structures 300, 302, located within the cutout/evacuated portions 210 not occupied by the embedded heat pipes 212. Stiffener structures 300, 302 may also be referred to as rods, embedded rods, embedded structural strengtheners, and the like.

In some embodiments, each of the stiffener structures may be attached to a top or bottom surface (e.g., along the z-direction) of the space formed by the cutout/evacuated portions 210. The top surface of the space formed by the cutout/evacuated portions 210 may comprise the underside of the fins 200, and the bottom surface of the space formed by the cutout/evacuated portions 210 may comprise the top of the central portion 220. For instance, stiffener structure 300 may be located between adjacent embedded heat pipes 212 along the bottom sides of the embedded heat pipes 212 or at the bottom of the cutout/evacuated portions 210; and stiffener structure 302 may be located between adjacent embedded heat pipes 212 along the top sides of the embedded heat pipes 212 or at the top of the cutout/evacuated portions 210. Stiffener structures included in the heatsink 102 may be sized to fit within the available empty space of the cutout/evacuated portions 210 in between the embedded heat pipes 212 (e.g., embedded heat pipes 212 need not be modified to accommodate the stiffener structures 300, 302).

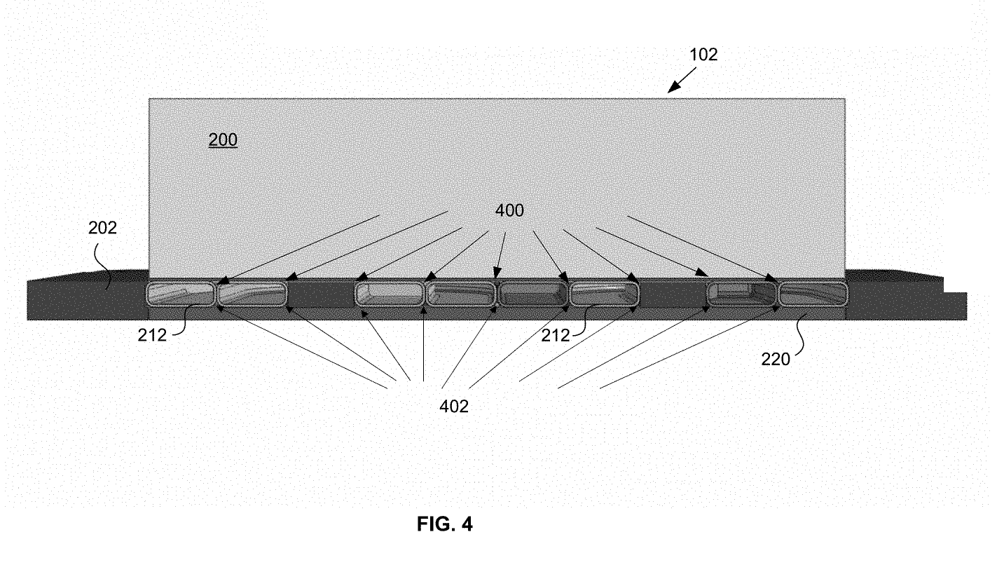

Not only may each of the stiffener structures be located by the top side or bottom side of the embedded heat pipes 212, the stiffener structure may also be located between any adjacent embedded heat pipes 212 such as at the midpoint, endpoint, or in between the mid- and end-points of the base 202. FIG. 4 depicts locations 400, 402 which may comprise examples of possible stiffener structure locations, according to some embodiments. As an example, heatsink 102 may include a single stiffener structure located at the bottom midpoint of the base 202 (e.g., stiffener structure 300). As another example, heatsink 102 may include two stiffener structures located respectively at the top midpoint and bottom midpoint of the base 202 (e.g., stiffener structures 300, 302). As still another example, heatsink 102 may include two stiffener structures located respectively at the bottom midpoint and bottom, right of the midpoint of the base 202. In yet another example, heatsink 102 may include more than two stiffener structures, half of the stiffener structures at the top side of the base 202 (e.g., among locations 400) and the remaining half of the stiffener structures at the bottom side of the base 202 (e.g., among locations 402).

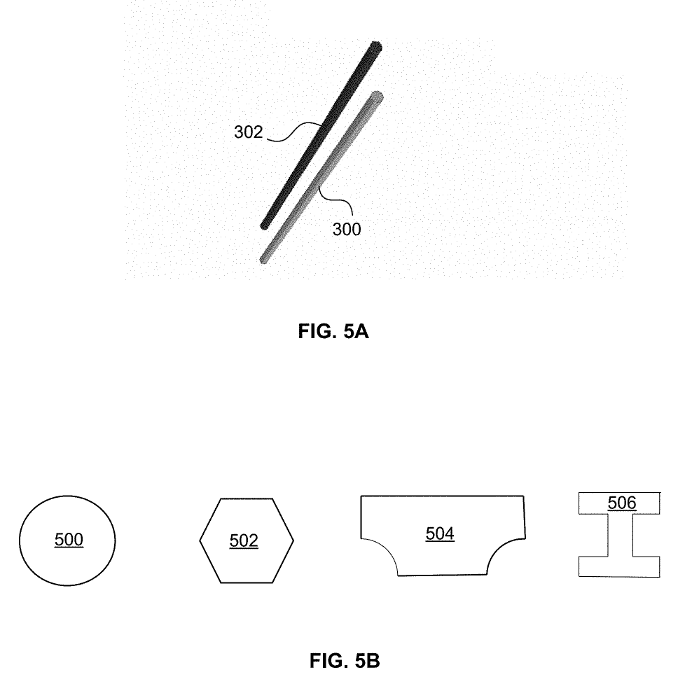

In some embodiments, stiffener structures 300, 302 may comprise solid structures that extend substantially along the length of the base 202. In FIG. 3, stiffener structures 300, 302 may extend substantially in the cutout/evacuated portions 210 substantially parallel to the length of the embedded heat pipes 212 (along the y-direction). FIG. 5A depicts a perspective view of stiffener structures 300, 302, according to some embodiments, illustrating the lengths or extensions of the stiffener structures 300, 302. In alternative embodiments, two or more stiffener structures may be connected to each other. For example, stiffener structures 300 and 302 may comprise a unitary structure having a C-shape, a U-shape, or an O-shape.

FIG. 5B depicts example cross sectional shapes of the one or more stiffener structures included in the heatsink 102, according to some embodiments. In some embodiments, the cross sectional shape of a stiffener structure may comprise a polygonal shape or closed shape. As shown in FIG. 5B, the stiffener structure may have a circular cross sectional shape 500. Alternatively, the stiffener structure may have a multi-sided polygon cross sectional shape 502, a T-shape 504, an I-shape (or I beam) shape 506, or the like. Each of the stiffener structures included in the heatsink 102 may have any of a variety of cross sectional shapes. If more than one stiffener structure may be included in the heatsink 102, each of the stiffener structures may have the same or different cross sectional shapes or sizes from each other. In some embodiments, the cross sectional diameter of the stiffener structure may be approximately 1 to 2 millimeters (mm) and the thickness of the base 202 may be approximately 4 to 5 mm.

In some embodiments, the material comprising the stiffener structure may be those having sufficiently high stiffness and/or yield strength properties, as needed to reduce warpage or deformation of the base 202 and/or yielding of the base 202 at local area(s) of the embedded heat pipes 212 under a higher load. The material may comprise a metallic or conductive material. Example materials for the stiffener structure may comprise, without limitation, any listed in the table below. Any other materials having similar stiffness and/or yield strength characteristics as those below may also be suitable for the stiffener structure.

| | | | Beryllium | Mild | Stainless | Cobalt- |
|---|---|---|---|---|---|---|
| | Aluminum | Copper | copper alloy | steel | steel | chrome |
| Stiffness: Young's | 68 | 110 | 125 | 200 | 190 | 220-258 |
| modulus (GigaPascal | | | | | | |
| (GPa)) | | | | | | |
| Strength: Yield | 240 to | 30 to | 250 to | 250 | 500 to | 450 to |
| strength (MegaPascal | approximately | approximately | approximately | | approximately | approximately |
| (MPa)) | 270 | 300 | 900 | | 1000 | 560 |

With the inclusion of the embedded heat pipes 212 but without the stiffener structures in the base 202, the stiffness of the base 202 may be approximately 850 lbf/mm under a point load. This stiffness value may further decrease once the heatsink including such a base is attached to the other components/layers to form a stacked structure. The formation of such a stacked structure may introduce a stack load that may fall below, for example, approximately 180 to 300 lbf/mm, especially in the center area of the heatsink. Too low of a stack load may compromise electrical, thermal, and/or reliability requirements of the stacked structure. In contrast, a solid copper base (e.g., without embedded heat pipes 212 nor the stiffener structures) may have a stiffness of approximately 1600 lbf/mm under a point load.

In some embodiments, with the inclusion of the stiffener structure(s) in the base 202, structural strengthening of the base 202 may be achieved without affecting functionality of the embedded heat pipes 212, thermal performance of the heatsink 102, and the like. The stiffener structure(s) included in the base 202 may prevent deformation or bending of the base 202 under load conditions and may also facilitate better contact with the IHS through TIM2. With the stiffener structure(s) in place, thermal performance of TIM2 may also be achieved. As the number of stiffener structures increases in the base 202, the greater the structural strengthening of the base 202, in general.

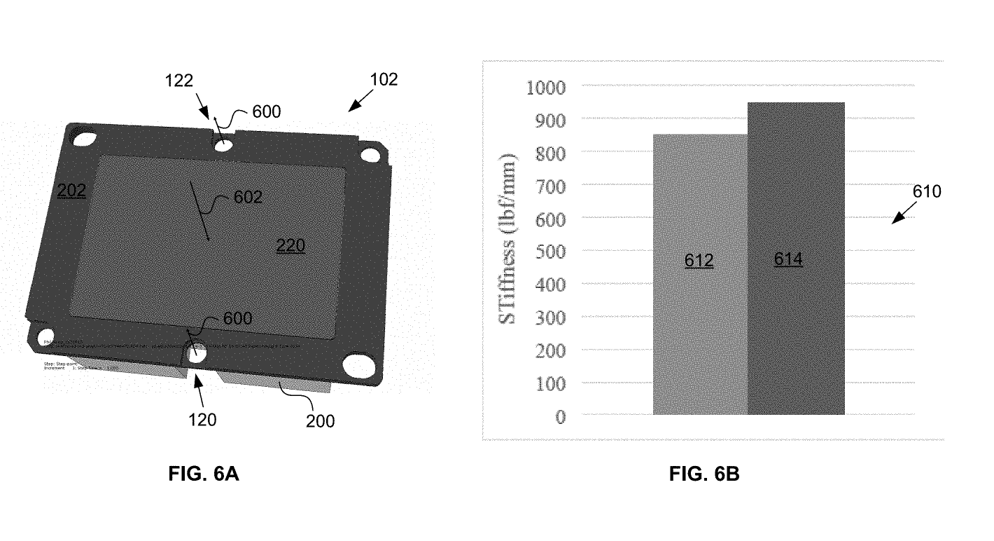

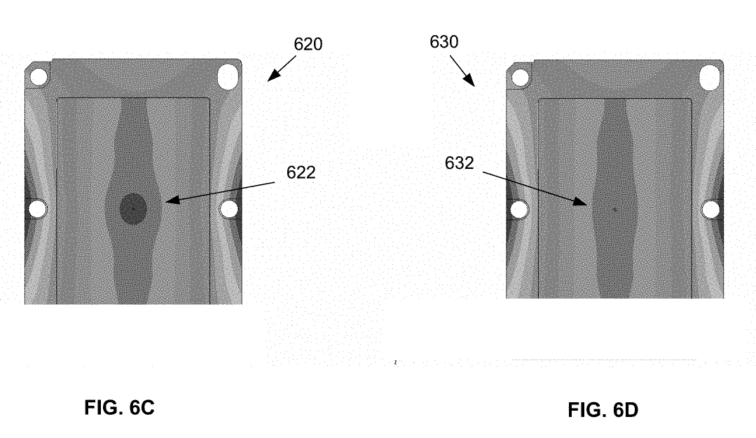

FIG. 6A depicts an illustration of simulated loads applicable to the heatsink 102 in a finite element analysis (FEA) simulation, according to some embodiments. The heatsink 102 shown in FIG. 6A may include two stiffener structures, e.g., stiffener structures 300, 302 as shown in FIG. 3. Loads 600 may be associated with attachment of the heatsink 102 to the other layers/components of the apparatus 100. Loads 600 may comprise, for example, two retention screw loads at the mounting/attachment sockets 120, 122. Loads 600 may be simulated to be 250 lbf/mm. Load 602 may be associated with a point load to the center of the base 202 which may be present by virtue of formation of the stacked structure of apparatus 100. Load 602 may represent a worst case load scenario and which may cause the maximum heatsink deflection, deformation, or warpage.

FIG. 6B depicts an example graph 610 illustrating FEA simulation results, according to some embodiments. Bar 612 shows a stiffness value of a base when no stiffener structure may be included (e.g., stiffness value of approximately 850 lbf/mm). Bar 614 shows a stiffness value of the base 202 with the inclusion of two stiffener structures (e.g., the simulated structure) (e.g., stiffness value of approximately 950 lbf/mm). As may be seen, the stiffness of the base 202 with the stiffener structures may be higher than a base without the stiffener structure. In particular, the inclusion of the stiffener structure may provide an 11.6% improvement/increase in stiffness to the base 202.

FIGS. 6C-6D depict examples of simulated deflection of the base 202 with and without stiffener structures, according to some embodiments. Comparing deflection diagram 620 associated with no stiffener structures to deflection diagram 630 associated with two stiffener structures, it may be seen that center area 622 in deflection diagram 620 may be darker in a larger area than corresponding center area 632 in deflection diagram 630. The darker an area, the greater the amount of deflection. Thus, the inclusion of stiffener structures to the base 202 (e.g., stiffener structures 300 and 302) may reduce or prevent warpage, deflection, or deformation of the base 202, in particular the center portion of the base 202. Such reduction may also provide improved thermal dissipation performance for the heatsink 102.

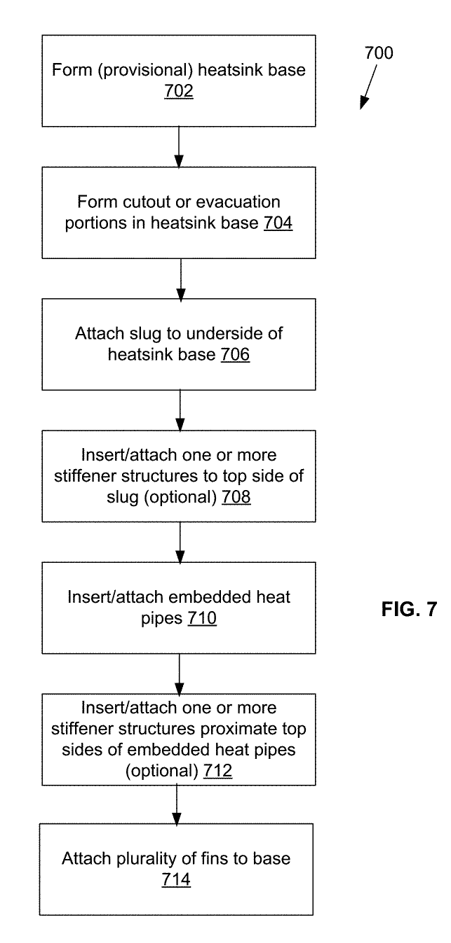

FIG. 7 depicts an example process 700 for fabricating the base 202, according to some embodiments. At a block 702, a solid heatsink base may be formed having the same overall dimensions and shape as base 202. The solid heatsink base may be formed using a stamping, molding, milling, or other such fabrication techniques. Next, at a block 704, a top side of the solid heatsink base formed in block 702 may be refined by removing certain portions to form the cutout/evacuation portions 210. A central portion of the underside of the solid heatsink base may also be removed to seat the central portion 220. Removal of select portions of the solid heatsink base may be formed using a milling, laser etching, or other such techniques. At a block 706, the central portion 220 may be positioned and attached to the underside of the now selectively contoured solid heatsink base.

Alternatively, blocks 702 and 704 may be performed simultaneously by forming or including the cutouts or evacuated portions simultaneous with formation of the heatsink base.

When stiffener structure(s) are to be disposed proximate a bottom side of the embedded heat pipes 212, one or more stiffener structures may be inserted and attached to select locations within the cutout/evacuation portions 210, at a block 708. Such stiffener structures may attach to a bottom side of the cutout/evacuation portions 210, which may comprise the top side of the central portion 220 in some embodiments. The stiffener structures may be attached using a soldering technique. If no stiffener structures are to be disposed proximate the bottom side of the embedded heat pipes 212, then block 708 may be omitted.

Next at a block 710, the embedded heat pipes 212 may be inserted and attached within the cutout/evacuation portions 210 not already occupied by the stiffener structure(s) of block 708. Then at a block 712, if stiffener structure(s) are to be included proximate a top side of the embedded heat pipes 212, then such stiffener structure(s) may be inserted and attached to select locations proximate the top side of the embedded heat pipes 212. The stiffener structures may be soldered to the underside of the plurality of fins 200 or a conductive or metallic layer between the embedded heat pipes 212 and the underside of the plurality of fins 200. Block 712 may be optional if no stiffener structures are to be included proximate the top side of the embedded heat pipes 212.

In embodiments, block 708 or block 712 or both may be performed in process 700, so that base 202 may be formed that includes at least one stiffener structure at a selected location within the base 202 as discussed above.

With the embedded heat pipes 212 and one or more stiffener structures in place within the base 202, the plurality of fins 200 may be attached to the top side of the base 202, at a block 714.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Illustrative examples of the devices, systems, and methods of various embodiments disclosed herein are provided below. An embodiment of the devices, systems, and methods may include any one or more, and any combination of, the examples described below.

Example 1 an apparatus including a plurality of thermal dissipation fins; and a base disposed below the plurality of thermal dissipation fins, wherein the base is to include an evacuated space in which one or more thermal transport pipes and one or more stiffener structures are disposed, the evacuated space is to include a first side proximate to the plurality of thermal dissipation fins and a second side opposite the first side, and wherein a stiffener structure of the one or more stiffener structures attaches to the first or second side.

Example 2 may include the subject matter of Example 1, and may further include wherein the stiffener structure of the one or more stiffener structures is disposed between adjacent thermal transport pipes of the one or more thermal transport pipes and proximate a top or bottom side of the one or more thermal transport pipes.

Example 3 may include the subject matter of any of Example 1-2, and may further include wherein the first side comprises an underside of the plurality of thermal dissipation fins and the stiffener structure of the one or more stiffener structures attaches to the first side.

Example 4 may include the subject matter of any of Example 1-3, and may further include wherein the first side comprises a top of an embedded slug included on an underside of the base furthest from the plurality of thermal dissipation fins, and the stiffener structure of the one or more stiffener structures attaches to the first side.

Example 5 may include the subject matter of any of Example 1-4, and may further include wherein the stiffener structure of the one or more stiffener structures extends within the evacuated space substantially parallel to a length of the one or more thermal transport pipes.

Example 6 may include the subject matter of any of Example 1-5, and may further include wherein the stiffener structure of the one or more stiffener structures comprises a cross sectional diameter of approximately 1 to 2 millimeters (mm).

Example 7 may include the subject matter of any of Example 1-6, and may further include wherein the stiffener structure of the one or more stiffener structures comprises a metallic material, a conductive material, aluminum, copper, beryllium copper alloy, mild steel, stainless steel, or cobalt-chrome.

Example 8 may include the subject matter of any of Example 1-7, and may further include wherein a cross sectional shape of the stiffener structure of the one or more stiffener structures comprises a polygon or closed shape.

Example 9 may include the subject matter of any of Example 1-8, and may further include wherein the one or more stiffener structures is to increase stiffness or yield strength or both of at least a portion of the base.

Example 10 may include the subject matter of any of Example 1-9, and may further include a computing component disposed below the base, and wherein heat generated by the computing component is to be dissipated by the one or more thermal transport pipes and the plurality of thermal dissipation fins.

Example 11 is a method including forming an evacuated space in a heatsink base; inserting one or more thermal transport pipes in the evacuated space; inserting and attaching one or more stiffener structures in respective portions of the evacuated space not occupied by the one or more thermal transport pipes; and attaching a plurality of thermal dissipation fins to the heatsink base.

Example 12 may include the subject matter of Example 11, and may further include wherein inserting and attaching the one or more stiffener structures comprises inserting and attaching the one or more stiffener structures to respective portions of a first side of the evacuated space, wherein the evacuated space includes the first side proximate to the plurality of thermal dissipation fins and a second side opposite the first side.

Example 13 may include the subject matter of any of Example 11-12, and may further include wherein inserting and attaching the one or more stiffener structures comprises inserting and attaching the one or more stiffener structures to respective portions of a second side of the evacuated space, wherein the evacuated space includes a first side proximate to the plurality of thermal dissipation fins and the second side opposite the first side.

Example 14 may include the subject matter of any of Example 11-13, and may further include wherein the first side comprises an underside of the plurality of thermal dissipation fins and the second side comprises an embedded slug included in an underside of the heatsink base furthest from the plurality of thermal dissipation fins.

Example 15 may include the subject matter of any of Example 11-14, and may further include wherein inserting and attaching the one or more stiffener structure comprises inserting and attaching the one or more stiffener structures between adjacent thermal transport pipes of the one or more thermal transport pipes and proximate a top or bottom side of the one or more thermal transport pipes.

Example 16 may include the subject matter of any of Example 11-15, and may further include wherein the one or more stiffener structures extend within the evacuated space substantially parallel to a length of the one or more thermal transport pipes, and the one or more stiffener structures comprise a metallic material, a conductive material, aluminum, copper, beryllium copper alloy, mild steel, stainless steel, or cobalt-chrome.

Example 17 is an apparatus including a heatsink that is to include a plurality of thermal dissipation fins disposed above a base; and a computing component disposed proximate to the heatsink, wherein the base of the heatsink is to include an evacuated space in which one or more thermal transport pipes and one or more stiffener structures are disposed, the evacuated space is to include a first side proximate to the plurality of thermal dissipation fins and a second side opposite the first side, and wherein a stiffener structure of the one or more stiffener structures attaches to the first or second side, and wherein heat generated by the computing component is to be dissipated by the one or more thermal transport pipes and the plurality of thermal dissipation fins.

Example 18 may include the subject matter of Example 17, and may further include wherein the stiffener structure of the one or more stiffener structures is disposed between adjacent thermal transport pipes of the one or more thermal transport pipes and proximate a top or bottom side of the one or more thermal transport pipes.

Example 19 may include the subject matter of any of Examples 17-18, and may further include wherein the first side comprises an underside of the plurality of thermal dissipation fins and the stiffener structure of the one or more stiffener structures attaches to the first side.

Example 20 may include the subject matter of any of Examples 17-19, and may further include wherein the first side comprises a top of an embedded slug included on an underside of the base furthest from the plurality of thermal dissipation fins, and the stiffener structure of the one or more stiffener structures attaches to the first side.

Example 21 may include the subject matter of any of Examples 17-20, and may further include wherein the stiffener structure of the one or more stiffener structures extends within the evacuated space substantially parallel to a length of the one or more thermal transport pipes.

Example 22 may include the subject matter of any of Examples 17-21, and may further include wherein the stiffener structure of the one or more stiffener structures comprises a cross sectional diameter of approximately 1 to 2 millimeters (mm).

Example 23 may include the subject matter of any of Examples 17-22, and may further include wherein the stiffener structure of the one or more stiffener structures comprises a metallic material, a conductive material, aluminum, copper, beryllium copper alloy, mild steel, stainless steel, or cobalt-chrome.

Example 24 may include the subject matter of any of Examples 17-23, and may further include wherein a cross sectional shape of the stiffener structure of the one or more stiffener structures comprises a polygon or closed shape.

Example 25 may include the subject matter of any of Examples 17-24, and may further include wherein the one or more stiffener structures is to increase stiffness or yield strength or both of at least a portion of the base.

Example 26 is an apparatus including means for thermal dissipation; and a base disposed below the means for thermal dissipation, wherein the base is to include an evacuated space in which means for thermal transport and means for stiffening the base are disposed, and wherein the means for stiffening the base is disposed between the means for thermal transport and proximate a side of the means for thermal transport closest or furthest from the means for thermal dissipation.

Example 27 may include the subject matter of Example 26, and may further include wherein the means for stiffening the base comprises one or more structures and the means for stiffening the base is disposed at select locations along a length of the base.

Example 28 may include the subject matter of any of Example 26-27, and may further include wherein the means for stiffening the base extend within the evacuated space substantially parallel to a length of the means for thermal transport.

Example 29 may include the subject matter of any of Example 26-28, and may further include wherein the means for stiffening the base comprises one or more structures, and a structure of the one or more structures has a cross sectional diameter of approximately 1 to 2 millimeters (mm).

Example 30 may include the subject matter of any of Example 26-29, and may further include wherein the means for stiffening the base comprises one or more structures, and a structure of the one or more structures has a cross sectional profile that comprises a polygon or closed shape.

Example 31 may include the subject matter of any of Example 26-30, and may further include wherein the means for stiffening the base comprises a metallic material, a conductive material, aluminum, copper, beryllium copper alloy, mild steel, stainless steel, or cobalt-chrome.

Example 32 may include the subject matter of any of Example 26-31, and may further include wherein the means for stiffening the base comprises means to increase stiffness or yield strength or both of at least a portion of the base.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

1. An apparatus comprising:
a plurality of thermal dissipation fins; and
a base disposed below the plurality of thermal dissipation fins, wherein the base is to include an evacuated space in which one or more thermal transport pipes and one or more stiffener structures are disposed to stiffen the base, the evacuated space is to include a first side proximate to the plurality of thermal dissipation fins and a second side opposite the first side, and wherein a stiffener structure of the one or more stiffener structures attaches to the first or second side.

2. The apparatus of claim 1, wherein the stiffener structure of the one or more stiffener structures is disposed between adjacent thermal transport pipes of the one or more thermal transport pipes and proximate a top or bottom side of the one or more thermal transport pipes.

3. The apparatus of claim 1, wherein the first side comprises an underside of the plurality of thermal dissipation fins and the stiffener structure of the one or more stiffener structures attaches to the first side.

4. The apparatus of claim 1, wherein the first side comprises a top of an embedded slug included on an underside of the base furthest from the plurality of thermal dissipation fins, and the stiffener structure of the one or more stiffener structures attaches to the first side.

5. The apparatus of claim 1, wherein the stiffener structure of the one or more stiffener structures extends within the evacuated space substantially parallel to a length of the one or more thermal transport pipes.

6. The apparatus of claim 1, wherein the stiffener structure of the one or more stiffener structures comprises a metallic material, a conductive material, aluminum, copper, beryllium copper alloy, mild steel, stainless steel, or cobalt-chrome.

7. The apparatus of claim 1, further comprising a computing component disposed below the base, and wherein heat generated by the computing component is to be dissipated by the one or more thermal transport pipes and the plurality of thermal dissipation fins.

8. A method comprising:
forming an evacuated space in a heatsink base;
inserting one or more thermal transport pipes in the evacuated space;
inserting and attaching one or more stiffener structures in respective portions of the evacuated space not occupied by the one or more thermal transport pipes to stiffen the base; and
attaching a plurality of thermal dissipation fins to the heatsink base.

9. The method of claim 8, wherein inserting and attaching the one or more stiffener structures comprises inserting and attaching the one or more stiffener structures to respective portions of a first side of the evacuated space, wherein the evacuated space includes the first side proximate to the plurality of thermal dissipation fins and a second side opposite the first side.

10. The method of claim 8, wherein inserting and attaching the one or more stiffener structures comprises inserting and attaching the one or more stiffener structures to respective portions of a second side of the evacuated space, wherein the evacuated space includes a first side proximate to the plurality of thermal dissipation fins and the second side opposite the first side.

11. The method of claim 10, wherein the first side comprises an underside of the plurality of thermal dissipation fins and the second side comprises an embedded slug included in an underside of the heatsink base furthest from the plurality of thermal dissipation fins.

12. The method of claim 8, wherein inserting and attaching the one or more stiffener structure comprises inserting and attaching the one or more stiffener structures between adjacent thermal transport pipes of the one or more thermal transport pipes and proximate a top or bottom side of the one or more thermal transport pipes.

13. An apparatus comprising:
a heatsink that is to include a plurality of thermal dissipation fins disposed above a base; and
a computing component disposed proximate to the heatsink, wherein the base of the heatsink is to include an evacuated space in which one or more thermal transport pipes and one or more stiffener structures are disposed to stiffen the base, the evacuated space is to include a first side proximate to the plurality of thermal dissipation fins and a second side opposite the first side, and wherein a stiffener structure of the one or more stiffener structures attaches to the first or second side, and wherein heat generated by the computing component is to be dissipated by the one or more thermal transport pipes and the plurality of thermal dissipation fins.

14. The apparatus of claim 13, wherein the stiffener structure of the one or more stiffener structures is disposed between adjacent thermal transport pipes of the one or more thermal transport pipes and proximate a top or bottom side of the one or more thermal transport pipes.

15. The apparatus of claim 13, wherein the first side comprises a top of an embedded slug included on an underside of the base furthest from the plurality of thermal dissipation fins, and the stiffener structure of the one or more stiffener structures attaches to the first side.

16. The apparatus of claim 13, wherein the stiffener structure of the one or more stiffener structures extends within the evacuated space substantially parallel to a length of the one or more thermal transport pipes.

17. The apparatus of claim 13, wherein a cross sectional shape of the stiffener structure of the one or more stiffener structures comprises a polygon or closed shape.

18. An apparatus comprising:
means for thermal dissipation; and
a base disposed below the means for thermal dissipation, wherein the base is to include an evacuated space in which means for thermal transport and means for stiffening the base are disposed, and wherein the means for stiffening the base is disposed between the means for thermal transport and proximate a side of the means for thermal transport closest or furthest from the means for thermal dissipation.

19. The apparatus of claim 18, wherein the means for stiffening the base comprises one or more structures and the means for stiffening the base is disposed at select locations along a length of the base.

20. The apparatus of claim 19, wherein the means for stiffening the base extend within the evacuated space substantially parallel to a length of the means for thermal transport.

21. The apparatus of claim 18, wherein the means for stiffening the base comprises one or more structures, and a structure of the one or more structures has a cross sectional diameter of approximately 1 to 2 millimeters (mm).

22. The apparatus of claim 18, wherein the means for stiffening the base comprises one or more structures, and a structure of the one or more structures has a cross sectional profile that comprises a polygon or closed shape.

23. The apparatus of claim 18, wherein the means for stiffening the base comprises a metallic material, a conductive material, aluminum, copper, beryllium copper alloy, mild steel, stainless steel, or cobalt-chrome.
